(19) United States
(12) Patent Application Publication
(10) Pub. No.: US 2025/0309180 A1
(43) Pub. Date: Oct. 2, 2025

(54) INTEGRATED CIRCUIT PACKAGES AND METHODS OF FORMING THE SAME

(71) Applicant: Taiwan Semiconductor Manufacturing Co., Ltd., Hsinchu (TW)

(72) Inventors: Wei-Yu Chen, Taipei (TW); Ching-Hua Hsieh, Hsinchu (TW); Hsiu-Jen Lin, Zhubei (TW); Hao-Jan Pei, Hsinchu (TW); Chao-Wei Chiu, Hsinchu (TW); Hsin Liang Chen, New Taipei (TW)

(21) Appl. No.: 19/237,461

(22) Filed: Jun. 13, 2025

Related U.S. Application Data
(63) Continuation of application No. 18/328,982, filed on Jun. 5, 2023.
(60) Provisional application No. 63/483,817, filed on Feb. 8, 2023.

(51) Int. Cl. H01L 23/00

(52) U.S. Cl. CPC H01L 24/73; H01L 24/11; H01L 24/16; H01L 24/27; H01L 24/32; H01L 24/81; H01L 24/92; H01L 2224/1184; H01L 2224/16145; H01L 2224/2784; H01L 2224/32145; H01L 2224/73204; H01L 2224/81203; H01L 2224/9211

(57) ABSTRACT

An embodiment is a device including a substrate comprising conductive pads, a package component bonded to the conductive pads of the substrate with solder connectors, the package component comprising an integrated circuit die, the integrated circuit die comprising die connectors, one of the solder connectors coupled to each of the die connectors and a corresponding conductive pad of the substrate, a first dielectric layer laterally surrounding each of the die connectors and a portion of the solder connectors, and a second dielectric layer being between the first dielectric layer and the substrate, the second dielectric layer laterally surrounding each of the conductive pads of the substrate.

### PRIORITY CLAIM AND CROSS-REFERENCE

This application is a continuation of U.S. patent application Ser. No. 18/328,982, filed Jun. 5, 2023, which claims the benefit of U.S. Provisional Application No. 63/483,817 filed on Feb. 8, 2023, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit die.

FIGS. 2-20 are views of intermediate stages in the manufacturing of integrated circuit packages, in accordance with some embodiments.

FIGS. 21-23 are views of intermediate stages in the manufacturing of integrated circuit packages, in accordance with some embodiments.

FIGS. 24-25 are views of intermediate stages in the manufacturing of integrated circuit packages, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, integrated circuit dies (sometimes referred to as chips) are coupled to wafers in a chip to wafer structure. In some embodiments, the chips are coupled to other chips in a chip to chip structure (sometimes referred to as a chip stack structure). In some embodiments, the chips are attached to the wafers with microbumps (e.g., conductive posts with solder). In some embodiments, the pitch of the microbumps is less than 10 μm. In the present disclosure, the microbumps can be formed within a multi-layered structure including a first layer and a second layer. The planarizing of the solder is performed with the first layer present but before the second layer is formed, which improves the solder coplanarity. Further, the second layer can have a lower fluidity than the solder at high temperatures, which prevents solder collapse and bridging. By improving the solder coplanarity and preventing solder collapse and solder bridging after the bump reflow, the yield and reliability of the packages is improved.

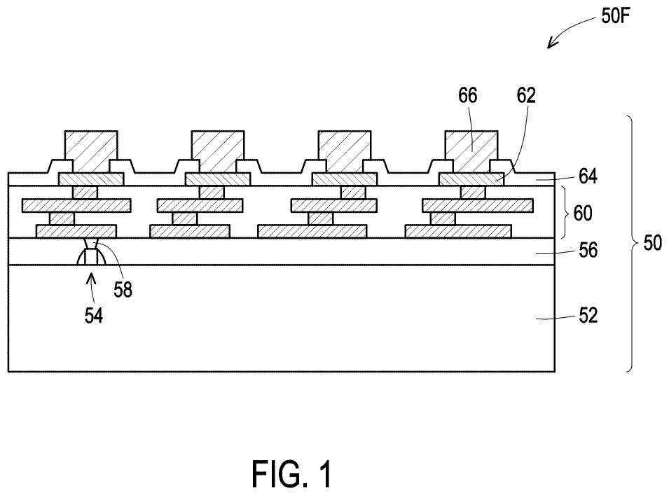

FIG. 1 illustrates a cross-sectional view of an integrated circuit die 50 in accordance with some embodiments. The integrated circuit die 50 will be packaged in subsequent processing to form an integrated circuit package. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front side, and an inactive surface (e.g., the surface facing downwards in FIG. 1), sometimes called a back side.

Devices (represented by a transistor) 54 may be formed at the front surface of the semiconductor substrate 52. The devices 54 may be active devices (e.g., transistors, diodes, etc.), capacitors, resistors, etc. An inter-layer dielectric (ILD) 56 is over the front surface of the semiconductor substrate 52. The ILD 56 surrounds and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 58 extend through the ILD 56 to electrically and physically couple the devices 54. For example, when the devices 54 are transistors, the conductive plugs 58 may couple the gates and source/drain regions of the transistors. Source/drain region(s) may refer to a source or a drain, individually or collectively dependent upon the context. The conductive plugs 58 may be formed of tungsten, cobalt, nickel, copper, silver, gold, aluminum, the like, or combinations thereof. An interconnect structure 60 is over the ILD 56 and conductive plugs 58. The interconnect structure 60 interconnects the devices 54 to form an integrated circuit. The interconnect structure 60 may be formed by, for example, metallization patterns in dielectric layers on the ILD 56. The metallization patterns include metal lines and vias formed in one or more low-k dielectric layers. The metallization patterns of the interconnect structure 60 are electrically coupled to the devices 54 by the conductive plugs 58.

The integrated circuit die 50 further includes pads 62, such as aluminum pads, to which external connections are made. The pads 62 are on the active side (sometimes referred to as the front-side 50F) of the integrated circuit die 50 of the integrated circuit die 50, such as in and/or on the interconnect structure 60. One or more passivation films 64 are on the integrated circuit die 50, such as on portions of the interconnect structure 60 and pads 62. Openings extend through the passivation films 64 to the pads 62. Die connectors 66, such as conductive pillars (for example, formed of a metal such as copper), extend through the openings in the passivation films 64 and are physically and electrically coupled to respective ones of the pads 62. The die connectors 66 may be formed by, for example, plating, or the like. The die connectors 66 electrically couple the respective integrated circuits of the integrated circuit die 50.

In some embodiments, the integrated circuit die 50 is a stacked device that includes multiple semiconductor substrates 52. For example, the integrated circuit die 50 may be a memory device such as a hybrid memory cube (HMC) module, a high bandwidth memory (HBM) module, or the like that includes multiple memory dies. In such embodiments, the integrated circuit die 50 includes multiple semiconductor substrates 52 interconnected by through-substrate vias (TSVs). Each of the semiconductor substrates 52 may (or may not) have an interconnect structure 60.

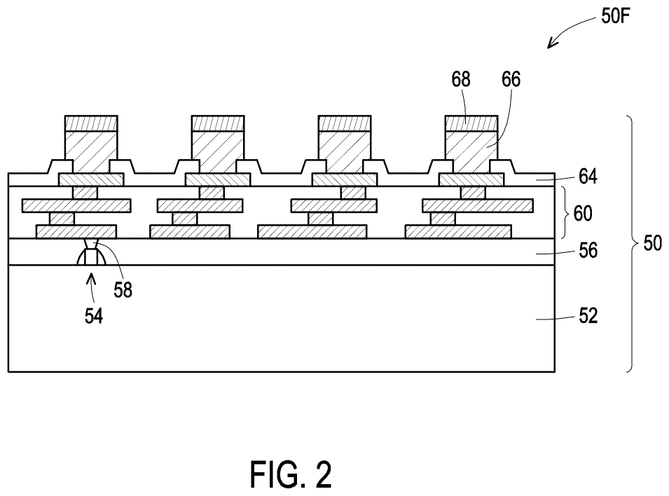

In FIG. 2, solder regions 68 (e.g., solder layers or solder bumps) are formed on the die connectors 66. The solder regions 68 may be formed of a conductive material that is reflowable, such as solder, copper, aluminum, gold, nickel, silver, palladium, tin, the like, or a combination thereof. In some embodiments, the solder regions 68 are formed by initially forming a layer of solder on the die connectors 66 through methods such as evaporation, electroplating, printing, solder transfer, ball placement, or the like. The solder regions 68 are used for electrically connecting the integrated circuit die 50 to other structures. The die connectors 66 and the solder regions 68 may be referred to as micro-bumps. The solder regions 68 may also be used to perform chip probe (CP) testing on the integrated circuit die 50. CP testing may be performed on the integrated circuit die 50 to ascertain whether the integrated circuit die 50 is a known good die (KGD). Thus, only integrated circuit dies 50, which are KGDs, undergo subsequent processing and are packaged, and dies, which fail the CP testing, are not packaged. After testing, the solder regions may be removed in subsequent processing steps.

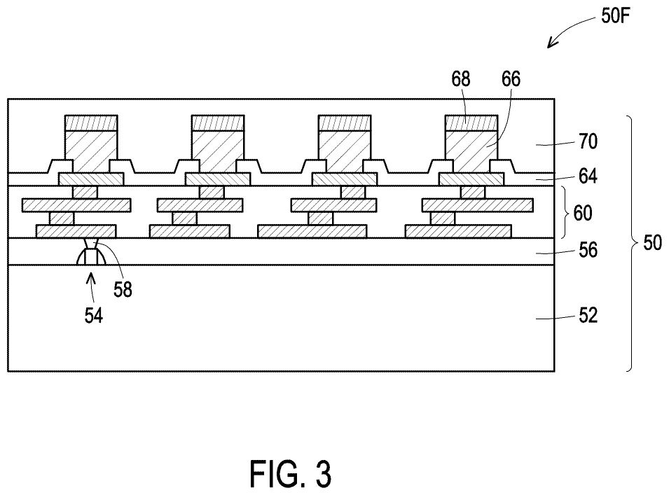

In FIG. 3, a dielectric layer 70 is formed on the active side of the integrated circuit die 50, such as on the passivation films 64, the die connectors 66, and solder regions 68. The dielectric layer 70 encapsulates the die connectors 66 and the solder regions 68, and the dielectric layer 70 may be laterally coterminous with the integrated circuit die 50. In some embodiments, the dielectric layer 70 buries the die connectors 66 and the solder regions 68, such that the topmost surface of the dielectric layer 70 is above the topmost surfaces of the solder regions 68.

The dielectric layer 70 may be a polymer such as polybenzoxazole (PBO), polyimide, benzocyclobutene (BCB), a molding compound, or the like. The dielectric layer 70 may include a base material, such as a polymer, and filler particles in the polymer. The filler particles may include dielectric particles of silicon oxide, aluminum oxide, silica, or the like, and may have spherical shapes. Also, the spherical filler particles may have the same or different diameters. In some embodiments, the diameters of the filler particles are less than 1 μm. The dielectric layer 70 may be formed, for example, by spin coating, lamination, liquid molding, chemical vapor deposition (CVD), or the like. In some embodiments, the dielectric layer 70 may be applied in liquid or semi-liquid form and then subsequently cured.

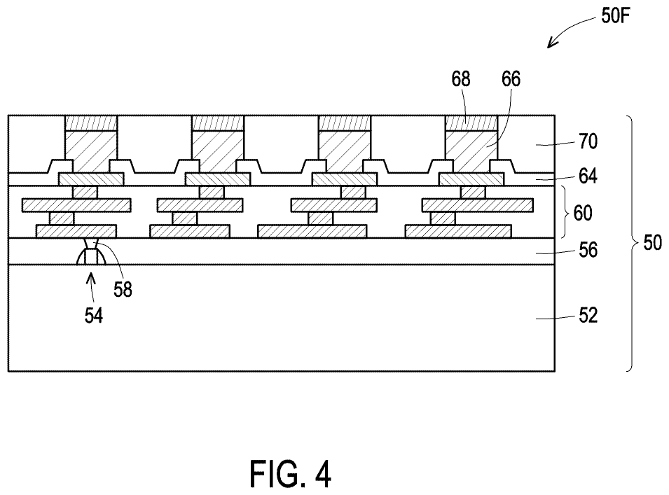

In FIG. 4, the dielectric layer 70 is planarized to expose the solder regions 68. The planarizing process may be a grinding process, a chemical-mechanical polish (CMP), an etch-back, combinations thereof, or the like. After the planarizing process, the top surfaces of the solder regions 68 and the dielectric layer 70 are coplanar (within process variations) such that they are level with one another. The planarizing is performed until a desired amount of the solder regions 68 and/or the dielectric layer 70 has been removed. In embodiments where the solder regions 68 are not buried in the dielectric layer 70, the planarizing process may be omitted.

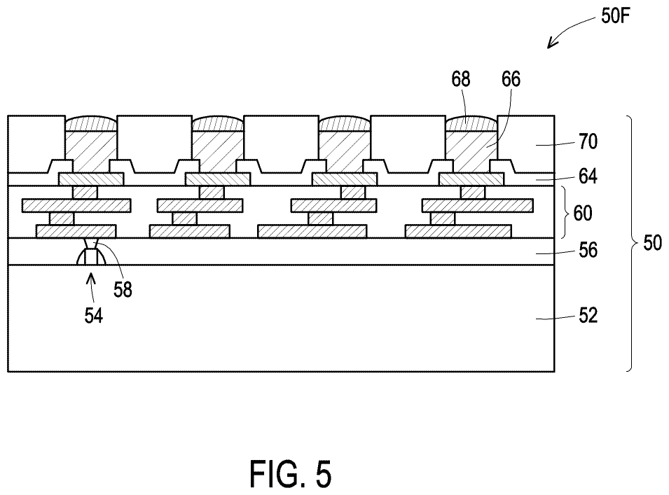

In FIG. 5, the solder regions 68 are formed into solder bumps 68. In some embodiments, a reflow process may be performed in order to shape the solder regions 68 into desired bump shapes.

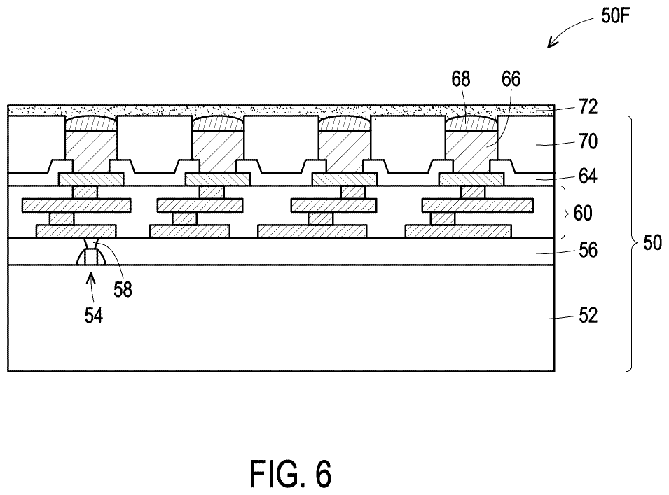

In FIG. 6, a coating 72 is formed on the active side of the integrated circuit die 50, such as on the dielectric layer 70 and solder regions 68. The coating 72 covers and reburies the solder regions 68 and may be laterally coterminous with the integrated circuit die 50. In some embodiments, the dielectric layer 70 buries the solder regions 68 and the dielectric layer 70, such that the topmost surface of the coating 72 is above the topmost surfaces of the solder regions 68 and the dielectric layer 70. In some embodiments, the coating 72 may be an adhesive, a flux, a non-conductive film, the like, or a combination thereof. In some embodiments, the coating 72 may be thinner than the dielectric layer 70. In some embodiments, the coating 72 may have a thickness in a range of 3 μm to 10 μm.

The coating 72 may include a base material and filler particles in the base material. The filler particles may include dielectric particles of silicon oxide, aluminum oxide, silica, or the like, and may have spherical shapes. Also, the spherical filler particles may have the same or different diameters. In some embodiments, the diameters of the filler particles are less than 1 μm. In some embodiments, the Young's modulus of the coating 72 is less than the Young's modulus of the dielectric layer 70. In some embodiments, the Young's modulus of each of the coating 72 and dielectric layer 70 is larger than that of a typical underfill material. Further, in some embodiments, the coefficient of thermal expansion of each of the coating 72 and dielectric layer 70 is smaller than that of a typical underfill material. The fluidity of each of the coating 72 and dielectric layer 70 can also be slower than that of solder during high temperature conditions, such as during reflow and bonding processes.

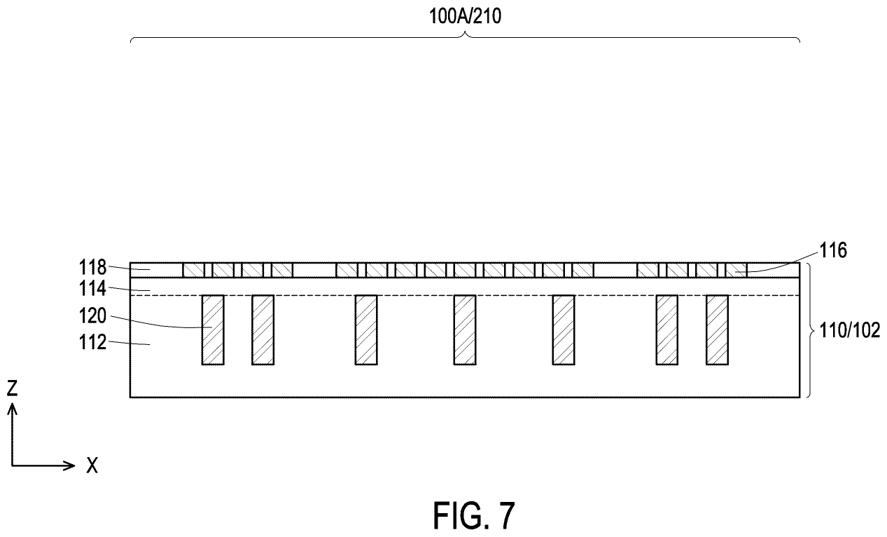

FIGS. 7-20 are views of intermediate stages in the manufacturing of integrated circuit packages 200, in accordance with some embodiments. FIGS. 7-19 are cross-sectional views and a plan view of a process for forming package components 210 which include interposers, such as package components for chip-on-wafer-on-substrate (CoWoS®) devices 200. The package components 210 may be chip-on-wafer (CoW) package components.

Although FIGS. 7-20 describe a chip-on-wafer-on-substrate device or a chip-on-wafer device, the wafer in these configuration could be replaced with a chip or die to a chip-on-chip device. In these embodiments, the chip or die may be formed in a similar manner as the integrated circuit die 50. Accordingly, the disclosure is not limited to wafer form structures but also includes embodiments with chip-on-chip structures.

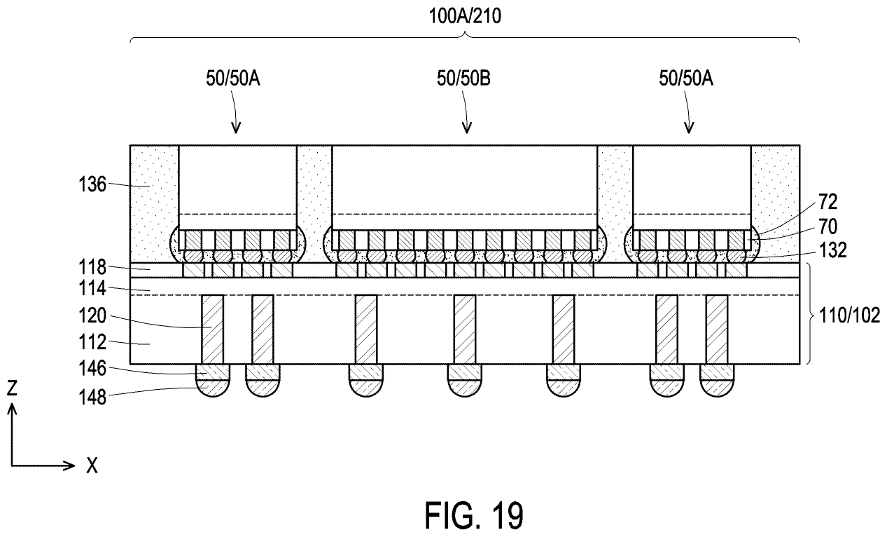

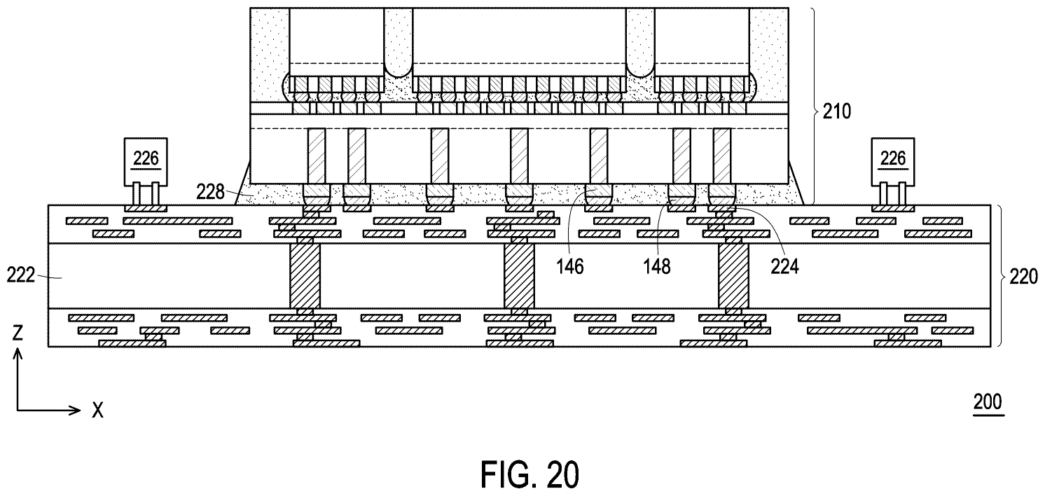

The integrated circuit packages 200 (see FIG. 19) will be formed by initially packaging integrated circuit dies 50 to form package components 210 in a wafer 100. One package region 100A of the wafer 100 is illustrated, and integrated circuit dies 50 are packaged to form a package component 210 in each of the package regions 100A of the wafer 100. It should be appreciated that any quantity of package regions can be simultaneously processed to form any quantity of package components. The package regions 100A of the wafer 100 will be singulated to form the package components 210. The package components 210 will be attached to package substrates 220 (see e.g., FIG. 20).

In FIG. 7, a wafer 110 is obtained or formed. The wafer 110 comprises devices in a package region 100A, which will be singulated in subsequent processing to be included in the package component 210. The devices in the wafer 110 may be interposers, integrated circuit dies, or the like. In some embodiments, interposers 102 are formed in the wafer 110, which include a substrate 112, an interconnect structure 114, and conductive vias 120. As discussed above, in some embodiments, the wafer 110 is a chip or die 110.

The substrate 112 may be a bulk semiconductor substrate, a semiconductor-on-insulator (SOI) substrate, a multi-layered semiconductor substrate, or the like. The substrate 112 may include a semiconductor material, such as silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The substrate 112 may be doped or undoped. In embodiments where interposers are formed in the wafer 110, the substrate 112 generally does not include active devices therein, although the interposers may include passive devices formed in and/or on a front surface (e.g., the surface facing upward in FIG. 7) of the substrate 112. In embodiments where integrated circuit devices are formed in the wafer 110, active devices such as transistors, capacitors, resistors, diodes, and the like, may be formed in and/or on the front surface of the substrate 112.

The interconnect structure 114 is over the front surface of the substrate 112, and is used to electrically connect the devices (if any) of the substrate 112. The interconnect structure 114 may include one or more dielectric layer(s) and respective metallization layer(s) in the dielectric layer(s). Acceptable dielectric materials for the dielectric layers include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobutene (BCB) based polymer, or the like. The metallization layer(s) may include conductive vias and/or conductive lines to interconnect any devices together and/or to an external device. The metallization layer(s) may be formed of a conductive material, such as a metal, such as copper, cobalt, aluminum, gold, combinations thereof, or the like. The interconnect structure 114 may be formed by a damascene process, such as a single damascene process, a dual damascene process, or the like.

In some embodiments, die connectors 116 and a dielectric layer 118 are at the front-side of the wafer 110. Specifically, the wafer 110 may include die connectors 116 (sometimes referred to as conductive pads 116) and a dielectric layer 118 that are similar to those of the integrated circuit die 50 described for FIG. 1. For example, the die connectors 116 and the dielectric layer 118 may be part of an upper metallization layer of the interconnect structure 114.

The conductive vias 120 extend into the interconnect structure 114 and/or the substrate 112. The conductive vias 120 are electrically connected to metallization layer(s) of the interconnect structure 114. The conductive vias 120 are also sometimes referred to as through substrate vias (TSVs). As an example to form the conductive vias 120, recesses can be formed in the interconnect structure 114 and/or the substrate 112 by, for example, etching, milling, laser techniques, a combination thereof, and/or the like. A thin dielectric material may be formed in the recesses, such as by using an oxidation technique. A thin barrier layer may be conformally deposited in the openings, such as by CVD, atomic layer deposition (ALD), physical vapor deposition (PVD), thermal oxidation, a combination thereof, and/or the like. The barrier layer may be formed of an oxide, a nitride, a carbide, combinations thereof, or the like. A conductive material may be deposited over the barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from a surface of the interconnect structure 114 or the substrate 112 by, for example, a CMP. Remaining portions of the barrier layer and conductive material form the conductive vias 120.

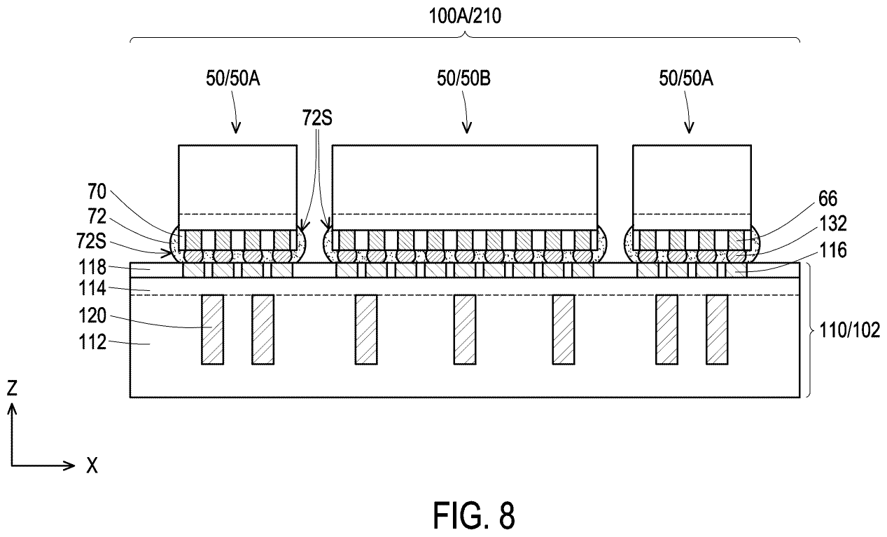

In FIG. 8, integrated circuit dies 50 (e.g., a first integrated circuit die 50A and a plurality of second integrated circuit dies 50B) are attached to the wafer 110. In the embodiment shown, multiple integrated circuit dies 50 are placed adjacent one another, including the first integrated circuit die 50A and the second integrated circuit dies 50B, where the first integrated circuit die 50A is between the second integrated circuit dies 50B. In some embodiments, the first integrated circuit die 50A is a logic device, such as a CPU, GPU, or the like, and the second integrated circuit dies 50B are memory devices, such as DRAM dies, HMC modules, HBM modules, or the like. In some embodiments, the first integrated circuit die 50A is the same type of device (e.g., SoCs) as the second integrated circuit dies 50B.

In the illustrated embodiment, the integrated circuit dies 50 are attached to the wafer 110 with solder bonds (e.g., from the solder regions 68) to form conductive connectors 132. The integrated circuit dies 50 may be placed on the interconnect structure 114 using, e.g., a pick-and-place tool. The conductive connectors 132 may be formed of the conductive material of the solder regions 68 of the integrated circuit dies 50 (see e.g., FIG. 6). Attaching the integrated circuit dies 50 to the wafer 110 may include placing the integrated circuit dies 50 on the wafer 110 performing a thermocompression bonding process to form the conductive connectors 132. For example, the integrated circuit dies 50 are placed on the wafer 100 and then pressed into wafer 110, e.g., as part of a thermocompression bonding process. The coating 72 is covering the solder regions 68 at the start of the thermocompression bonding process but after the process, the solder regions 68 physically contact the connectors 116 and extend through the coating 72. The conductive connectors 132 form joints between corresponding die connectors 116 of the wafer 110 and die connectors 66 the integrated circuit dies 50, electrically connecting the interposer 102 to the integrated circuit dies 50.

After the bonding process, the coating 72 and the dielectric layer 70 surrounds the conductive connectors 132. The coating 72 fills the area between the integrated circuit dies 50 and the wafer 110. In some embodiments, the coating 72 extends up to the sidewalls of the integrated circuit dies 50 and protrudes out from the area between the integrated circuit dies 50 and the wafer 110. In some embodiments, the coating 72 has curved sidewalls 72S that protrude outward from the sides of the integrated circuit dies 50. In some embodiments, the curved sidewalls 72S are convex shaped.

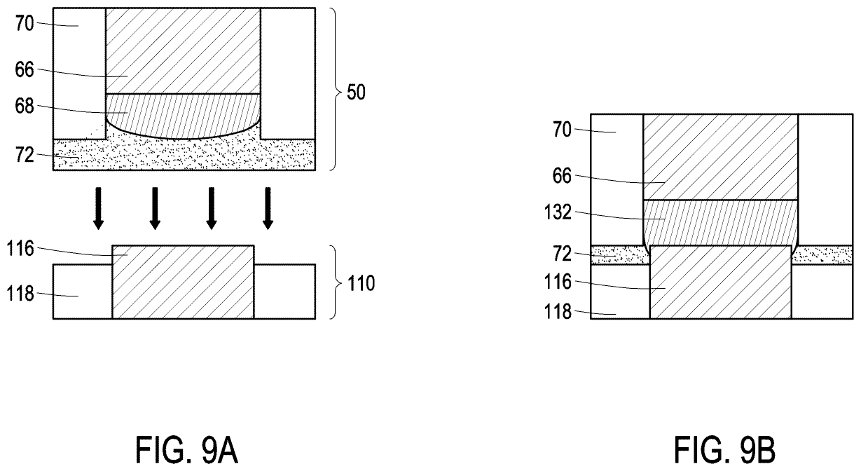

FIGS. 9A and 9B illustrate detailed views of the bonding process of a single conductive connector 132. In FIG. 9A, the die connector 66 and solder region 68 of the integrated circuit die 50 are aligned with the connector 116 of the wafer 110. In FIG. 9B, the die connector 66 and solder region 68 of the integrated circuit die 50 are placed on the connector 116 of the wafer 110. During the placing, the coating 72 is brought into physical contact with the connector 116 and the dielectric layer 118 of the wafer 110. In embodiments with a thermocompression bonding process, the integrated circuit dies 50 are then pressed into wafer 110 such that the solder region 68 of the integrated circuit die 50 physically contacts the connector 116 of the wafer 110 to form the conductive connector 132. In some embodiments, the solder regions 68 are in physical contact with the connectors 116 before the pressing and in other embodiments the solder regions 68 are brought into contact with the connectors 116 due to the pressing. In some embodiments, after the bonding process, the coating 72 separates the dielectric layers 70 and 118.

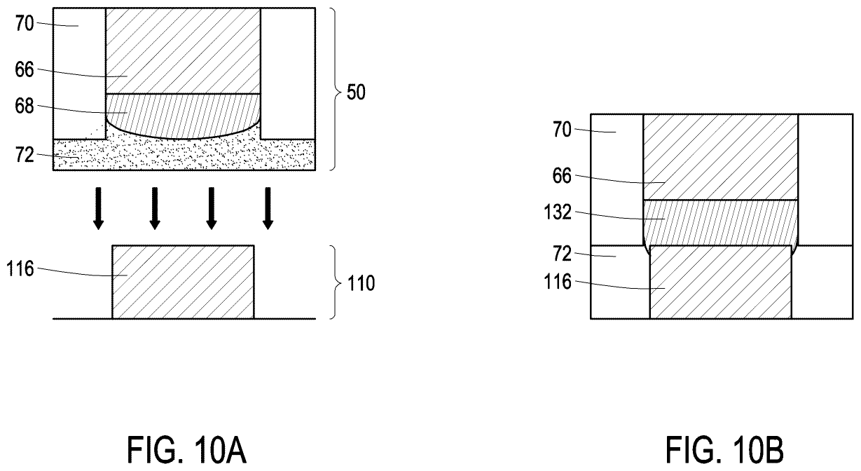

FIGS. 10A and 10B illustrate a similar intermediate step in processing is FIGS. 9A and 9B, except in this embodiment, the wafer 110 does not include the dielectric 118 (or the connector 116 extends above the dielectric layer 118 such that the coating 72 may not physically contact the dielectric layer 118. In this embodiment, the coating 72 surrounds the connector 116 and, in some embodiments, surrounds portions of the conductive connector 132. Other details of FIGS. 10A and 10B may be similar to those described above in FIGS. 9A and 9B and are not repeated herein.

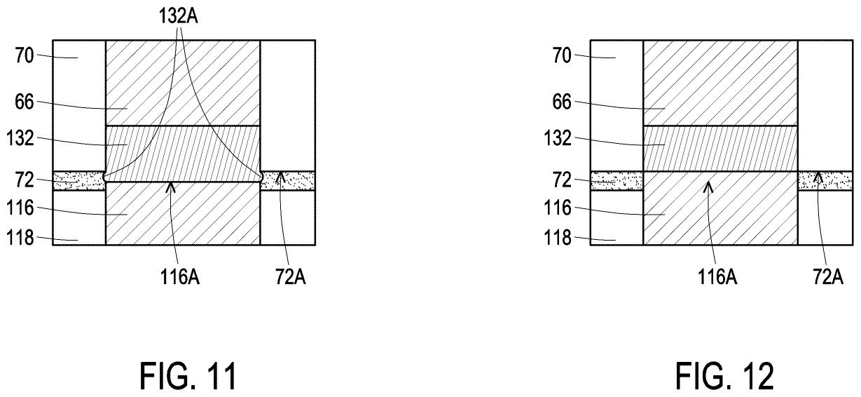

Various configurations of the dielectric layer 70, coating 72, die connector 66, conductive connector 132, connector 116, and dielectric layer 118 are within the scope of the present disclosure. Some of these configurations are described below in reference to FIGS. 11-16.

FIG. 11 illustrates a detailed view of a single conductive connector 132 in accordance with some embodiments. In FIG. 11, a top surface 72A of the coating 72 extends above a top surface 116A of the connector 116. In some embodiments, the conductive connector 132 has protruding portions 132A extending into the coating 72. The protruding portions 132A of the conductive connector 132 may cover portions of the sidewalls of the connector 116.

FIG. 12 illustrates a detailed view of a single conductive connector 132 in accordance with some embodiments. In FIG. 12, the top surface 72A of the coating 72 is substantially coplanar with the top surface 116A of the connector 116. In some embodiments, the conductive connector 132 has substantially vertical sidewalls confined by the dielectric layer 70. In some embodiments, the sidewalls of the conductive connector 132 are completely covered by the dielectric layer 70.

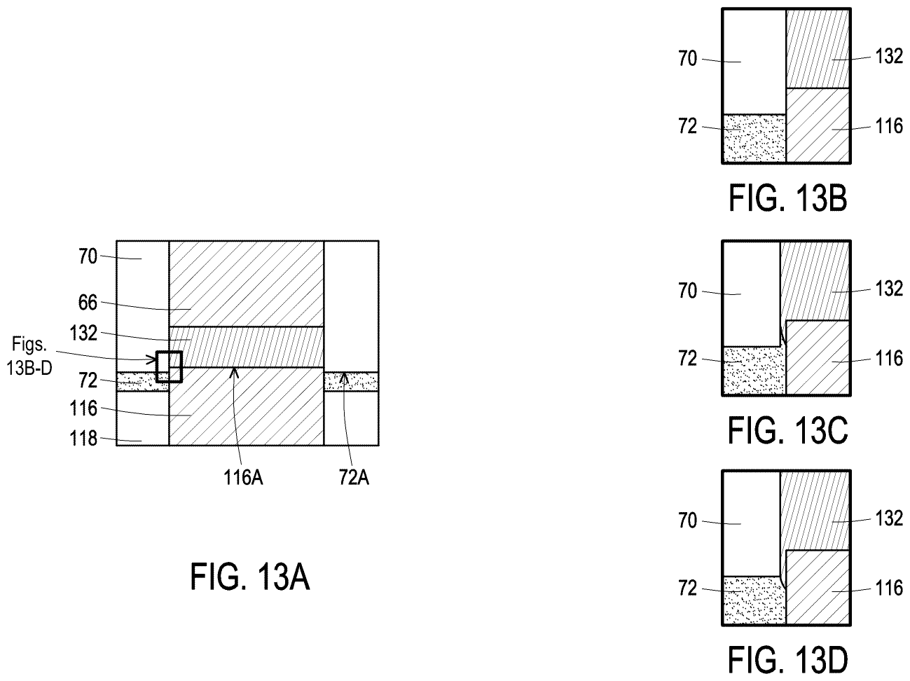

FIG. 13A illustrates a detailed view of a single conductive connector 132 in accordance with some embodiments. FIGS. 13B, 13C, and 13D illustrated detailed views of a portion of 13A. In FIGS. 13A-D, the top surface 72A of the coating 72 is below the top surface 116A of the connector 116 such that the connector 116 is inserted into the dielectric layer 70.

In FIG. 13B, the sidewalls of the conductive connector 132 are completely covered by the dielectric layer 70. In this embodiment, the conductive connector 132 may also have substantially vertical sidewalls confined by the dielectric layer 70.

In FIG. 13C, the coating 72 physically contacts sidewall of the conductive connector 132 and physically contacts and covers an inner sidewall (sidewall facing the conductive connector 132) of the dielectric layer 70. In some embodiments, the coating 72 covers a portion of the sidewall of the conductive connector 132.

In FIGS. 13C and 13D, the conductive connector 132 extends into the coating 72 to cover a portion of the sidewall of the connector 116.

Although, FIGS. 13A-D are illustrated as different embodiments, the present disclosure covers embodiments that combine the features of FIGS. 13A-D into various configurations.

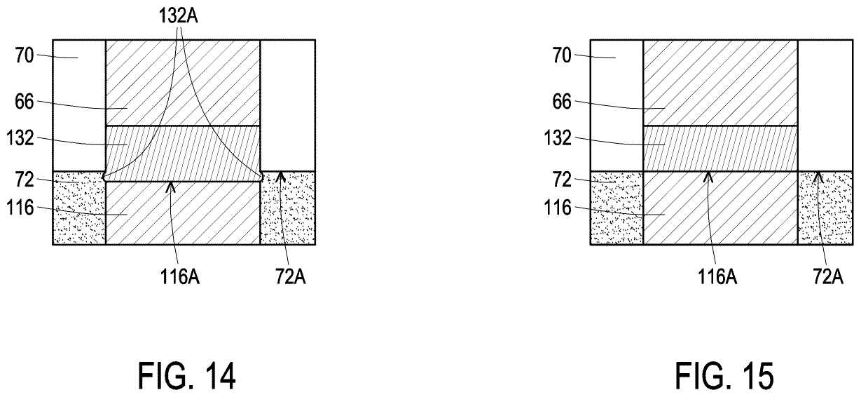

FIG. 14 illustrates a detailed view of a single conductive connector 132 in accordance with some embodiments. FIG. 14 illustrates the top surface 72A of the coating 72 being above the top surface 116A of the connector 116. The embodiment of FIG. 14 is similar to the embodiment of FIG. 11 with the embodiment of FIG. 14 not including the dielectric layer 118 (see e.g., FIGS. 10A and 10B). FIG. 11 was described above and the similar features of FIG. 14 are not repeated herein. In this embodiment, the coating 72 may completely cover the sidewalls of the connector 116 as the dielectric layer 118 is omitted.

FIG. 15 illustrates a detailed view of a single conductive connector 132 in accordance with some embodiments. FIG. 14 illustrates the top surface 72A of the coating 72 being substantially coplanar with the top surface 116A of the connector 116. The embodiment of FIG. 15 is similar to the embodiment of FIG. 12 with the embodiment of FIG. 14 not including the dielectric layer 118 (see e.g., FIGS. 10A and 10B). FIG. 12 was described above and the similar features of FIG. 15 are not repeated herein. In this embodiment, the coating 72 may completely cover the sidewalls of the connector 116 as the dielectric layer 118 is omitted.

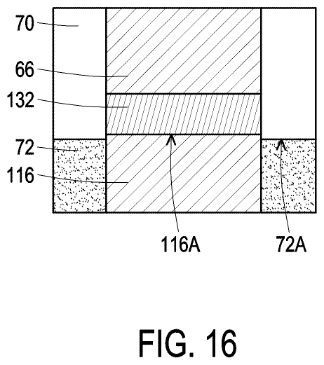

FIG. 16 illustrates a detailed view of a single conductive connector 132 in accordance with some embodiments. FIG. 16 illustrates the top surface 72A of the coating 72 being below the top surface 116A of the connector 116. The embodiment of FIG. 16 is similar to the embodiment of FIGS. 13A-D with the embodiment of FIG. 16 not including the dielectric layer 118 (see e.g., FIGS. 10A and 10B). FIGS. 13A-D were described above and the similar features of FIG. 16 are not repeated herein. In this embodiment, the coating 72 may completely cover the sidewalls of the connector 116 as the dielectric layer 118 is omitted.

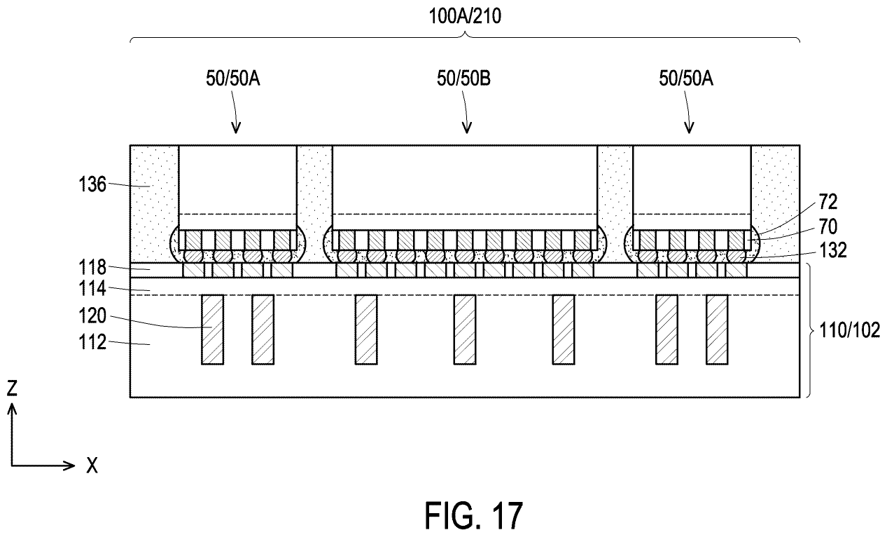

In FIG. 17, an encapsulant 136 is formed on and around the integrated circuit dies 50. After formation, the encapsulant 336 encapsulates the integrated circuit dies 50, the dielectric layer 70, and the coating 72. The encapsulant 136 may be a molding compound, epoxy, or the like. The encapsulant 136 may be applied by compression molding, transfer molding, or the like, and is formed over the wafer 110 such that the integrated circuit dies 50 are buried or covered. The encapsulant 136 may be applied in liquid or semi-liquid form and then subsequently cured. The encapsulant 136 may be thinned to expose the integrated circuit dies 50. The thinning process may be a grinding process, a chemical-mechanical polish (CMP), an etch-back, combinations thereof, or the like. After the thinning process, the top surfaces of the integrated circuit dies 50 and the encapsulant 136 are coplanar (within process variations) such that they are level with one another. The thinning is performed until a desired amount of the integrated circuit dies 50 and/or the encapsulant 136 has been removed.

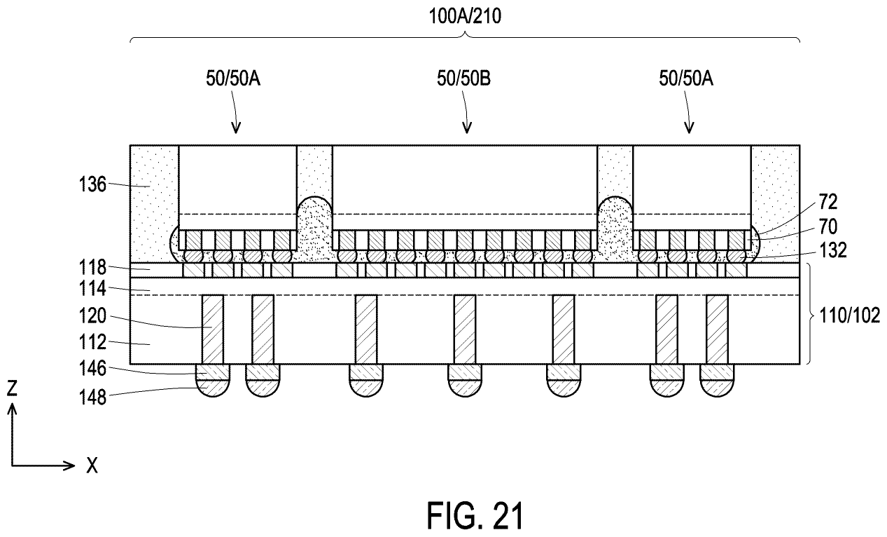

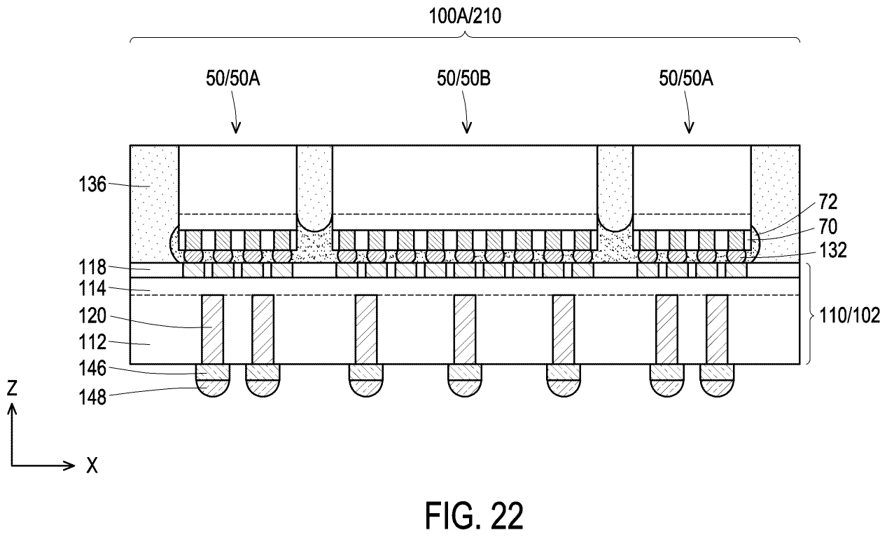

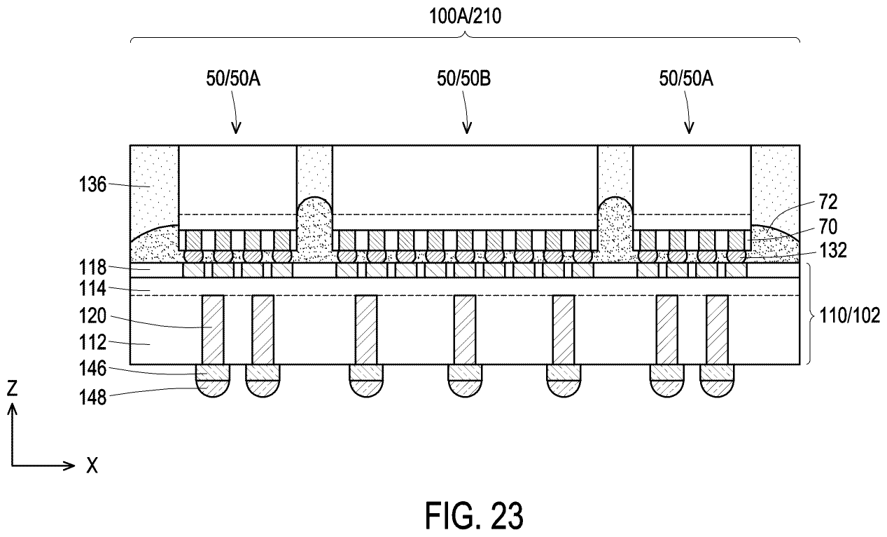

As illustrated in FIG. 17, the encapsulant 136 separates the coating 72 of adjacent integrated circuit dies 50 from each other. In some embodiments, the coating 72 of adjacent integrated circuit dies 50 may merge together between the adjacent integrated circuit dies 50 such that the encapsulant 136 does not separate them (see e.g., FIGS. 21-23). In those embodiments, the encapsulant 136 is over the merged coating 72 and may have a curved interface with the merged coating 72 between adjacent integrated circuit dies 50. In some embodiments, the curved interface can include a coating 72 with a convex upward interface (see e.g., FIG. 21 or 23) or a concave upward interface (see e.g., FIG. 22).

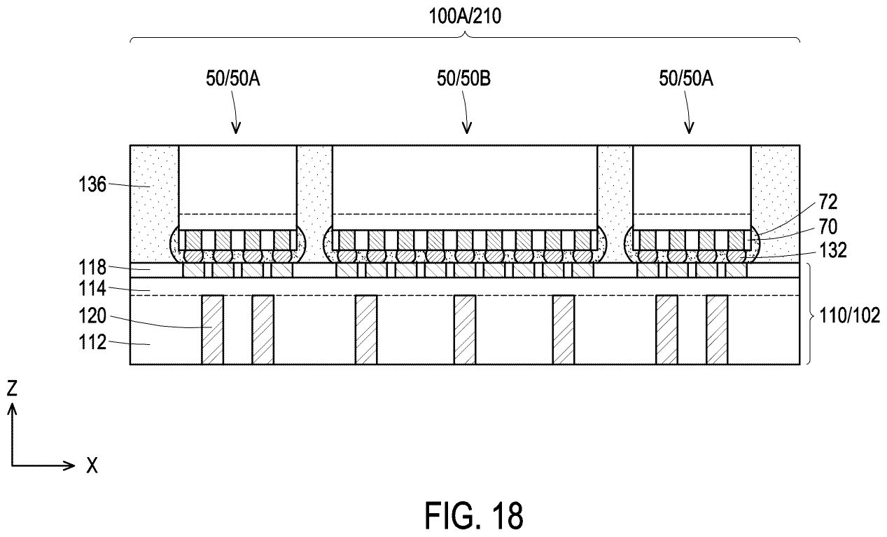

In FIG. 18, the substrate 112 is thinned to expose the conductive vias 130. Exposure of the conductive vias 130 may be accomplished by a thinning process, such as a grinding process, a chemical-mechanical polish (CMP), an etch-back, combinations thereof, or the like. In some embodiments (not separately illustrated), the thinning process for exposing the conductive vias 130 includes a CMP, and the conductive vias 130 protrude at the back-side of the wafer 110 as a result of dishing that occurs during the CMP. In such embodiments, an insulating layer (not separately illustrated) may optionally be formed on the back surface of the substrate 112, surrounding the protruding portions of the conductive vias 130. The insulating layer may be formed of a silicon-containing insulator, such as, silicon nitride, silicon oxide, silicon oxynitride, or the like, and may be formed by a suitable deposition method such as spin coating, CVD, plasma-enhanced CVD (PECVD), high density plasma CVD (HDP-CVD), or the like. After the substrate 112 is thinned, the exposed surfaces of the conductive vias 130 and the insulating layer (if present) or the substrate 112 are coplanar (within process variations) such that they are level with one another, and are exposed at the back-side of the wafer 110.

In FIG. 19, UBMs 146 are formed on the exposed surfaces of the conductive vias 130 and the substrate 112. As an example to form the UBMs 146 in this embodiment, a seed layer (not separately illustrated) is formed over the exposed surfaces of the conductive vias 130 and the substrate 112. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMs 146. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the UBMs 146.

Further, conductive connectors 148 are formed on the UBMs 146. The conductive connectors 148 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 148 may include a conductive material such as solder, copper, aluminum, gold, nickel, silver, palladium, tin, the like, or a combination thereof. In some embodiments, the conductive connectors 148 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 148 comprise metal pillars (such as copper pillars) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

Further, a singulation process is performed by cutting along scribe line regions, e.g., around the package region 100A. The singulation process may include sawing, dicing, or the like. For example, the singulation process can include sawing the encapsulant 136, the interconnect structure 114, and the substrate 112. The singulation process singulates the package region 100A from adjacent package regions. The resulting, singulated package component 210 is from the package region 100A. The singulation process forms interposers 102 from the singulated portions of the wafer 110. As a result of the singulation process, the outer sidewalls of the interposer 102 and the encapsulant 136 are laterally coterminous (within process variations).

In some embodiments, the package components 210 may be attached to package substrates. In FIG. 20, a package component 210 is attached to a package substrate 220 using the conductive connectors 148. The package substrate 220 includes a substrate core 222, which may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, or the like, may also be used. Additionally, the substrate core 222 may be a SOI substrate. Generally, an SOI substrate includes a layer of a semiconductor material such as epitaxial silicon, germanium, silicon germanium, SOI, SGOI, or combinations thereof. In another embodiment, the substrate core 222 is an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for the substrate core 222.

The substrate core 222 may include active and passive devices (not separately illustrated). Devices such as transistors, capacitors, resistors, combinations thereof, and the like may be used to generate the structural and functional requirements of the design for the system. The devices may be formed using any suitable methods.

The substrate core 222 may also include metallization layers and vias, and bond pads 224 over the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material, and may be formed through any suitable process (such as deposition, damascene, or the like). In some embodiments, the substrate core 222 is substantially free of active and passive devices.

The conductive connectors 148 are reflowed to attach the UBMs 146 to the bond pads 224. The conductive connectors 148 connect the package component 210, including the metallization layers 144 of the redistribution structure 140, to the package substrate 220, including metallization layers of the substrate core 222. Thus, the package substrate 220 is electrically connected to the integrated circuit dies 50. In some embodiments, passive devices (e.g., surface mount devices (SMDs), not separately illustrated) may be attached to the package component 210 (e.g., bonded to the UBMs 146) prior to mounting on the package substrate 220. In such embodiments, the passive devices may be bonded to a same surface of the package component 210 as the conductive connectors 148. In some embodiments, passive devices 226 (e.g., SMDs) may be attached to the package substrate 220, e.g., to the bond pads 224.

In some embodiments, an underfill 228 is formed between the package component 210 and the package substrate 220, surrounding the conductive connectors 148. The underfill 228 may be formed by a capillary flow process after the package component 210 is attached or may be formed by any suitable deposition method before the package component 210 is attached. The underfill 228 may be a continuous material extending from the package substrate 220 to the substrate 112.

Although not illustrated, the package substrate 220 can have conductive connectors formed on bond pads on the opposite side of the package substrate 220 (bottom side in FIG. 20) from the package component 210. Further, although not illustrated, the package substrate 220 can have lids/heat dissipation structures attached to the package component 210 and/or the package substrate 220.

FIGS. 21, 22, and 23 illustrate various configurations of the coating 72 and the encapsulant 136. In FIG. 21, the coating 72 of adjacent integrated circuit dies 50 is merged together between the adjacent integrated circuit dies 50 such that the encapsulant 136 does not separate the coating 72. The merging may occur due to a thicker coating 72 being applied over the dielectric layer 70 and the solder regions 68.

In FIG. 21, an interface between the merged coating 72 is a curved interface and the merged coating 72 has a convex upward interface. In FIG. 22, the interface between the merged coating 72 is a curved interface and the merged coating 72 has a concave upward interface. The concave upward interface of the coating 72 may be caused by differences in the Young's modulus of the coating 72 and the encapsulant 136 and/or by pressure applied during the encapsulation process. For example, if the coating 72 has a lower Young's modulus than the encapsulant 136, the coating 72 may have a concave upward interface with the encapsulant 136.

In FIG. 23, the coating 72 is within the scribe line region of the package region 100A. In this embodiment, the singulation process can include sawing the encapsulant 136, the coating 72, the interconnect structure 114, and the substrate 112. Although this embodiment is illustrated with the merged coating 72 having a convex upward interface, it is not limited to this and for example, the merged coating 72 could have a concave upward interface.

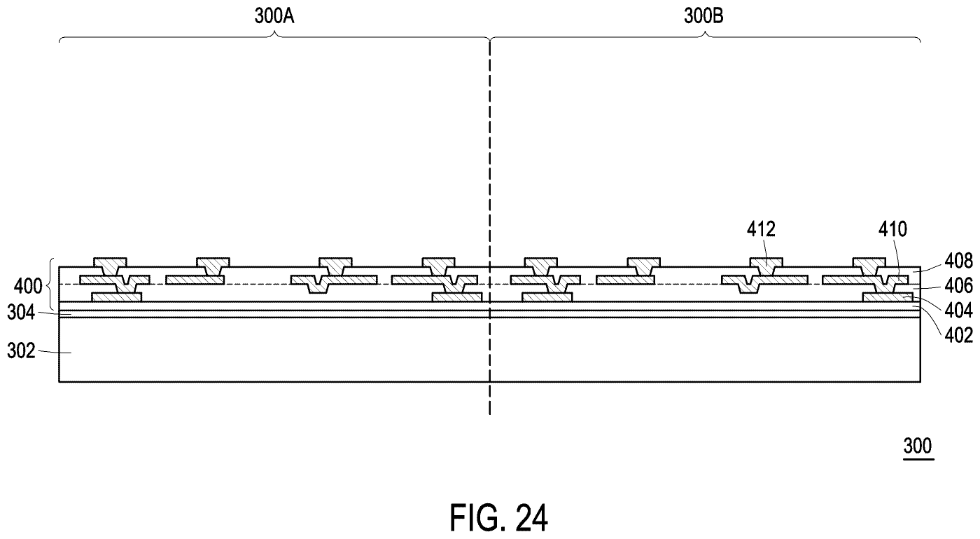

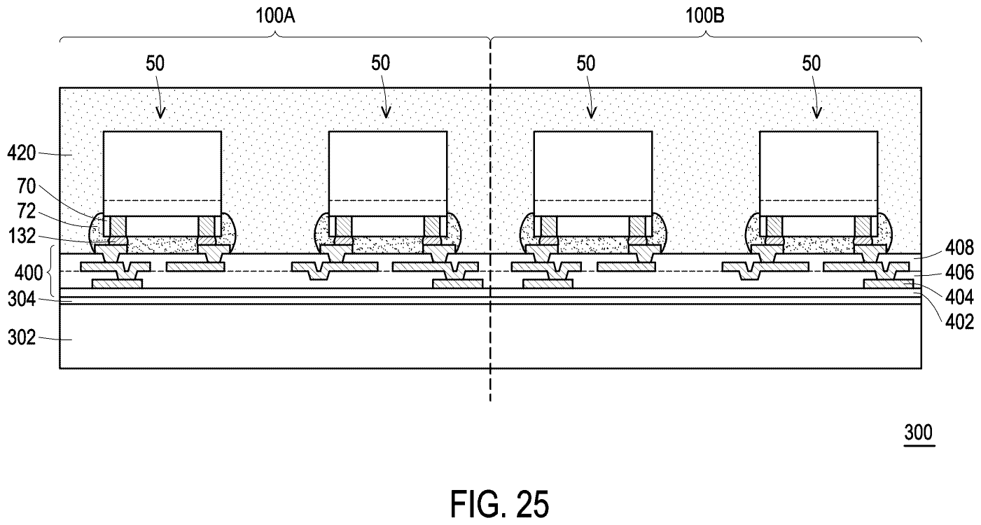

FIGS. 24 and 25 are views of intermediate stages in the manufacturing of integrated circuit packages in accordance with some embodiments. Specifically, this embodiment includes the integrated circuit dies 50 being bonded to a redistribution structure 400. The details of this embodiment that are similar to the previous embodiment are not repeated herein.

Referring to FIG. 24, a redistribution structure 400 may be formed on a release layer 304 over a carrier substrate 302. The carrier substrate 302 may be a glass carrier substrate, a ceramic carrier substrate, or the like. The carrier substrate 302 may be a wafer, such that multiple packages can be formed on the carrier substrate 302 simultaneously.

The release layer 304 may be formed of a polymer-based material, which may be removed along with the carrier substrate 302 from the overlying structures that will be formed in subsequent steps. In some embodiments, the release layer 304 is an epoxy-based thermal-release material, which loses its adhesive property when heated, such as a light-to-heat-conversion (LTHC) release coating. In other embodiments, the release layer 304 may be an ultra-violet (UV) glue, which loses its adhesive property when exposed to UV lights. The release layer 304 may be dispensed as a liquid and cured, may be a laminate film laminated onto the carrier substrate 302, or may be the like. The top surface of the release layer 304 may be leveled and may have a high degree of planarity.

Further, in FIG. 24, the redistribution structure 400 is formed over the release layer 304 and the carrier substrate 302. The redistribution structure 400 includes dielectric layers 402, 406, and 408; and metallization patterns 404 and 410. The metallization patterns may also be referred to as redistribution layers or redistribution lines. The redistribution structure 400 is shown as an example having three layers of metallization patterns. More or fewer dielectric layers and metallization patterns may be formed in the redistribution structure 400. If fewer dielectric layers and metallization patterns are to be formed, steps and process discussed below may be omitted. If more dielectric layers and metallization patterns are to be formed, steps and processes discussed below may be repeated.

The dielectric layer 402 is deposited on the release layer 304. In some embodiments, the dielectric layer 402 is formed of a photo-sensitive material such as PBO, polyimide, BCB, or the like, which may be patterned using a lithography mask. The dielectric layer 402 may be formed by spin coating, lamination, CVD, the like, or a combination thereof.

The metallization pattern 404 is then formed. The metallization pattern 404 includes conductive elements extending along the major surface of the dielectric layer 402. As an example to form the metallization pattern 404, a seed layer is formed over the dielectric layer 402. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 404. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern 404. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

The dielectric layer 406 is deposited on the metallization pattern 404 and the dielectric layer 402. The dielectric layer 406 may be formed in a manner similar to the dielectric layer 402, and may be formed of a similar material as the dielectric layer 402. The dielectric layer 406 is then patterned. The patterning forms openings exposing portions of the dielectric layer 402. The patterning may be by an acceptable process, such as by exposing and developing the dielectric layer 406 to light when the dielectric layer 406 is a photo-sensitive material or by etching using, for example, an anisotropic etch.

The metallization pattern 410 is then formed. The metallization pattern 410 includes portions on and extending along the major surface of the dielectric layer 406. The metallization pattern 410 further includes portions extending through the dielectric layer 406 to physically and electrically couple the metallization pattern 404. The metallization pattern 410 may be formed in a similar manner and of a similar material as the metallization pattern 404. In some embodiments, the metallization pattern 410 has a different size than the metallization pattern 404. For example, the conductive lines and/or vias of the metallization pattern 410 may be wider or thicker than the conductive lines and/or vias of the metallization pattern 404. Further, the metallization pattern 410 may be formed to a greater pitch than the metallization pattern 404.

The dielectric layer 408 is deposited on the metallization pattern 410 and the dielectric layer 406. The dielectric layer 408 may be formed in a manner similar to the dielectric layer 402, and may be formed of the same material as the dielectric layer 402. The dielectric layer 408 is the topmost dielectric layer of the redistribution structure 400.

The metallization pattern 412 is then formed. The metallization pattern 412 (sometimes referred to as underbump metallizations (UBMs)) includes portions on and extending along the major surface of the dielectric layer 408. The metallization pattern 412 further includes portions extending through the dielectric layer 408 to physically and electrically couple the metallization pattern 410. The metallization pattern 412 may be formed in a similar manner and of a similar material as the metallization pattern 404 and 410. The metallization pattern 412 is the topmost metallization pattern of the redistribution structure 400. In some embodiments, the metallization pattern 412 has a different size than the metallization patterns 410 and 404. For example, the conductive lines and/or vias of the metallization pattern 412 may be wider or thicker than the conductive lines and/or vias of the metallization patterns 410 and 404. Further, the metallization pattern 412 may be formed to a greater pitch than the metallization pattern 410. In some embodiments, the metallization pattern 412 may provide UBMs for the redistribution structure 400.

In FIG. 25, the integrated circuit dies 50 are attached to the redistribution structure 400 with solder bonds, such as conductive connectors. The integrated circuit dies 50 have been described above and the description is not repeated herein. The integrated circuit dies 50 may be placed on the redistribution structure 400 using, e.g., a pick-and-place tool and bonded with a similar method as described above (see FIGS. 8 through 16). Similar to the previous embodiments, an encapsulant 420 may then be formed around the integrated circuit dies, the dielectric layer 70, and the coating 72 and over the redistribution structure 400. Similar to the previous embodiments, the package regions 100A and 100B may be singulated into package structures 300. As a result of the singulation process, the outer sidewalls of the redistribution structure 600 and the encapsulant 420 are laterally coterminous (within process variations).

Although not shown, the carrier substrate 302 may be de-bonded to detach (or “de-bond”) the carrier substrate 302 from the redistribution structure 400, e.g., the dielectric layer 402. In accordance with some embodiments, the de-bonding includes projecting a light such as a laser light or an UV light on the release layer 304 so that the release layer 304 decomposes under the heat of the light and the carrier substrate 302 can be removed. After the de-bonding process, conductive connectors and UBMs may be formed extending through the dielectric layer 402 to contact the metallization pattern 404.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments may achieve advantages. In some embodiments, integrated circuit dies (sometimes referred to as chips) are coupled to wafers in a chip to wafer structure. In some embodiments, the chips are attached to the wafers with microbumps (e.g., conductive posts with solder). In some embodiments, the pitch of the microbumps is less than 10 μm. In the present disclosure, the microbumps can be formed within a multi-layered structure including a first layer and a second layer. The planarizing of the solder is performed with the first layer present but before the second layer is formed, which improves the solder coplanarity. Further, the second layer can have a lower fluidity than the solder at high temperatures, which prevents solder collapse and bridging. By improving the solder coplanarity and preventing solder collapse and solder bridging after the bump reflow, the yield and reliability of the packages is improved.

An embodiment is a device including a substrate comprising conductive pads, a package component bonded to the conductive pads of the substrate with solder connectors, the package component comprising an integrated circuit die, the integrated circuit die comprising die connectors, one of the solder connectors coupled to each of the die connectors and a corresponding conductive pad of the substrate, a first dielectric layer laterally surrounding each of the die connectors and a portion of the solder connectors, and a second dielectric layer being between the first dielectric layer and the substrate, the second dielectric layer laterally surrounding each of the conductive pads of the substrate.

In some embodiments, the second dielectric layer is an adhesive, a flux, a non-conductive film, or a combination thereof, the second dielectric layer laterally surrounds a portion of each of the solder connectors, one of the solder connectors protrudes outward into the second dielectric layer, a top surface of the second dielectric layer is coplanar with a top surface of one of the conductive pads, a top surface of the second dielectric layer is below a top surface of one of the conductive pads, a top surface of the second dielectric layer is above a top surface of one of the conductive pads, the second dielectric layer extends up to a sidewall of the integrated circuit die, wherein a sidewall of the second dielectric layer is curved and protruding outward from the integrated circuit die, and/or the substrate is a second integrated circuit die.

An embodiment is a method including forming microbumps on a first side of an integrated circuit die, each of the microbumps including a conductive post with a solder region on the conductive post, forming a first dielectric layer on the first side of the integrated circuit die and at least laterally surrounding the microbumps, planarizing the microbumps and the first dielectric layer, reflowing the solder regions of the planarized microbumps, the reflowing forming solder bumps on the conductive posts, forming a second dielectric layer over the first dielectric layer and the solder bumps of the microbumps, and bonding the first side of the integrated circuit die to conductive pads of a wafer with the microbumps, the solder bumps of the microbumps physically contacting the conductive pads of the wafer.

In some embodiments, after bonding the first side of the integrated circuit die to conductive pads of the wafer with the microbumps, the second dielectric layer laterally surrounding each of the conductive pads of the wafer. In some embodiments, after bonding the first side of the integrated circuit die to conductive pads of the wafer with the microbumps, the second dielectric layer laterally surrounding each of the solder bumps of the microbumps. In some embodiments, after bonding the first side of the integrated circuit die to conductive pads of the wafer with the microbumps, the solder bumps of the microbumps covers portions of sidewalls of the conductive pads of the wafer. In some embodiments, after bonding the first side of the integrated circuit die to conductive pads of the wafer with the microbumps, the solder bumps of the microbumps extend laterally into the second dielectric layer. In some embodiments, bonding the first side of the integrated circuit die to conductive pads of a wafer with the microbumps comprises performing a thermocompression bonding process. In some embodiments, the second dielectric layer is an adhesive, a flux, a non-conductive film, or a combination thereof. In some embodiments, the conductive pads of the wafer extend into the first dielectric layer.

An embodiment a method including forming microbumps on a first side of an integrated circuit die, each of the microbumps including a conductive post with a solder region on the conductive post, depositing a first dielectric layer on the first side of the integrated circuit die, the first dielectric layer burying the solder regions of the microbumps, grinding the first dielectric layer to expose the solder regions of the microbumps, reflowing the solder regions of the microbumps, the reflowing forming solder bumps on the conductive posts, forming a second dielectric layer over the first dielectric layer and the solder bumps of the microbumps, and performing a thermocompression bonding process to bond the microbumps of the integrated circuit die to conductive pads of a wafer, the solder bumps of the microbumps physically contacting the conductive pads of the wafer, the second dielectric layer covering the solder bumps at a start of the thermocompression bonding process.

In some embodiments, the second dielectric layer is an adhesive, a flux, a non-conductive film, or a combination thereof. In some embodiments, the conductive pads of the wafer extend into the first dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an interposer comprising conductive vias;
a plurality of integrated circuit dies bonded to the interposer;
a first dielectric layer surrounding connectors between the integrated circuit dies and the interposer;
a second dielectric layer between the first dielectric layer and the interposer, wherein the second dielectric layer comprises curved sidewalls protruding outward from sides of the integrated circuit dies, the second dielectric layer has a lower Young's modulus than the first dielectric layer, and the second dielectric layer is configured to have a lower fluidity than solder during solder reflow; and
an encapsulant surrounding the integrated circuit dies and the second dielectric layer.

2. The semiconductor device of claim 1, wherein the first dielectric layer comprises a polymer selected from the group consisting of polybenzoxazole, polyimide, and benzocyclobutene.

3. The semiconductor device of claim 1, wherein the second dielectric layer comprises a material selected from the group consisting of an adhesive, a flux, and a non-conductive film.

4. The semiconductor device of claim 1, wherein the second dielectric layer is configured solder collapse and bridging between adjacent connectors.

5. The semiconductor device of claim 1, wherein the curved sidewalls of the second dielectric layer are convex shaped.

6. The semiconductor device of claim 1, wherein the connectors between the integrated circuit dies and the interposer have a pitch less than 10 μm.

7. The semiconductor device of claim 1, wherein the second dielectric layer extends up to the sidewalls of the integrated circuit dies.

8. A chip-on-wafer-on-substrate assembly, comprising:
a package substrate;
an interposer bonded to the package substrate;
a plurality of integrated circuit dies bonded to the interposer;
a first dielectric layer surrounding die connectors of the integrated circuit dies;
a second dielectric layer between the first dielectric layer and the interposer;
wherein the second dielectric layer has a lower coefficient of thermal expansion than an underfill material; and
wherein the second dielectric layer extends up to sidewalls of the integrated circuit dies.

9. The assembly of claim 8, wherein the second dielectric layer has a lower Young's modulus than the first dielectric layer.

10. The assembly of claim 8, wherein the second dielectric layer prevents solder collapse and bridging between adjacent die connectors.

11. The assembly of claim 8, wherein the second dielectric layer comprises curved sidewalls protruding outward from sides of the integrated circuit dies.

12. The assembly of claim 8, wherein the first dielectric layer comprises a polymer and the second dielectric layer comprises an adhesive.

13. The assembly of claim 8, further comprising an underfill material between the interposer and the package substrate.

14. The assembly of claim 8, wherein the plurality of integrated circuit dies comprises a logic die and at least one memory die.

15. A method, comprising:
forming a redistribution structure comprising alternating dielectric and metallization layers on a carrier substrate;
attaching integrated circuit dies to the redistribution structure;
forming a first dielectric layer surrounding die connectors of the integrated circuit dies;
forming a second dielectric layer between the first dielectric layer and the redistribution structure;
wherein the second dielectric layer has a lower fluidity than solder at high temperatures;
encapsulating the integrated circuit dies, the first dielectric layer, and the second dielectric layer with an encapsulant; and
removing the carrier substrate.

16. The method of claim 15, further comprising planarizing the first dielectric layer to expose solder regions on the integrated circuit dies before forming the second dielectric layer.

17. The method of claim 15, wherein forming the second dielectric layer comprises applying a material selected from the group consisting of an adhesive, a flux, and a non-conductive film.

18. The method of claim 15, further comprising performing a reflow process to shape solder regions on the integrated circuit dies into solder bumps before forming the second dielectric layer.

19. The method of claim 15, wherein the second dielectric layer prevents solder collapse and bridging between adjacent die connectors during attachment of the integrated circuit dies to the redistribution structure.

20. The method of claim 15, further comprising singulating the encapsulated structure to form individual package components.
